(19) United States
(12) Patent Application Publication
(10) Pub. No.: US 2010/0128544 A1
(43) Pub. Date: May 27, 2010

(54) Bit line bridge detecting method in semiconductor memory device

(75) Inventors: Hyun-Ki Kim, Suwon-si (KR); Chi-Wook Kim, Hwaseong-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/591,073

(22) Filed: Nov. 6, 2009

(30) Foreign Application Priority Data
Nov. 27, 2008 (KR) 10-2008-0118497

(51) Int. Cl. G11C 29/00; G11C 7/00; G11C 7/06

(52) U.S. Cl. 365/201; 365/203; 365/205

(57) ABSTRACT

The method of detecting the bit line bridge in a semiconductor memory device includes enabling a sensing state for an even bit line connected to an even sense amplifier and an odd bit line connected to an odd sense amplifier, where the odd bit line is adjacent to the even bit line, first changing the odd bit line to a pre-charge state to pre-charge the odd bit line while maintaining the sensing state of the even bit line, second changing the odd bit line to a floating state, and applying a pause time period.

### PRIORITY STATEMENT

This application claims priority under 35 U.S.C. §119 from Korean Patent Application 10-2008-0118497, filed on Nov. 27, 2008, the contents of which are hereby incorporated by reference in their entirety as if fully set forth herein.

### BACKGROUND

1. Field

Example embodiments relate to testing a semiconductor memory device, for example, to a bit line bridge detecting method for use in a semiconductor memory device, where the method is capable of removing or reducing an overkill factor.

2. Description of the Related Art

In general, users are requiring semiconductor memory devices that have higher speeds and higher integration, e.g., dynamic random access memory (hereafter, referred to as “DRAM”). The DRAM generally includes unit memory cells, with each of the unit memory cells having an access transistor and a storage capacitor. The DRAM is usually employed as a main memory device in an electronic system.

Most semiconductor memory devices, such as the DRAM, include an array of memory cells coupled with intersections of bit lines (hereafter, referred to as “BL”) and word lines (hereafter, referred to as “WL”). Data having a value of “0” or “1” is written to at least one memory cell and the written data is read from the at least one memory cell through a sense amplifier.

As memory devices are becoming more highly-integrated, it is becoming increasingly difficult to fabricate the memory devices without any bridges forming between the plurality of bit lines or word lines, which may factor into causing a defect in the memory device. For example, a bridge between adjacent bit lines (hereafter, referred to as “bit line bridge”) may be caused by particles during a fabrication process. If the bit line bridge functions as a path of leakage current between the adjacent bit lines during write or read operations of the memory device, the memory device may not operate properly.

In general, an effect of the bridge becomes stronger or more damaging as a size or dimension of a pattern in the memory device decreases. For example, if lines are cut or are circuit-shorted (or short circuited) with an adjacent line, a failed unit memory cell may be simply detected by current bridge detecting methods during testing. In this case, the failed unit memory cell may be repaired by substituting the memory cell connected with the lines having the defect with a spare cell using a redundancy technology. However, if a smaller bridge circuit or micro bridge occurs between adjacent lines, the memory device having the micro bridge circuit may be not be detected by the current bridge detecting methods during testing. Thus, a failed unit memory cell may not be detected until later, such as when the memory device is being used in a field. Accordingly, the current bridge detecting methods may be deficient in precision and/or response time for micro bridges. Furthermore, when an overkill factor exists in the current bridge detecting methods, a unit memory cell may be incorrectly detected as a failed unit memory cell, and thus a precision or accuracy of the current bridge detecting methods during testing is lowered.

### SUMMARY

Example embodiments provide a method of detecting a bit line bridge in a semiconductor memory device, which is capable of removing or reducing an overkill factor. When a bridge occurs between bit lines or memory cells, the bridge may be detected relatively quickly and precisely according to example embodiments. A detection error from leakage current of a bit line sense amplifier may be reduced or eliminated in detecting a bridge between bit lines or memory cells, according to example embodiments.

According to example embodiments, a method of detecting a bit line bridge in a semiconductor memory device includes enabling a sensing state for an even bit line connected to an even sense amplifier and an odd bit line connected to an odd sense amplifier, where the odd bit line is adjacent to the even bit line, first changing the odd bit line to a pre-charge state to pre-charge the odd bit line while maintaining the sensing state of the even bit line, second changing the odd bit line to a floating state, and applying a pause time period.

In example embodiments, the enabling includes enabling a first word line, where the first word line intersects the odd and even bit lines, and activating the even and odd sense amplifiers.

In example embodiments, the method further includes sustaining the pre-charge state of the odd bit line when the first word line is enabled after the first changing.

In example embodiments, the method further includes enabling a second word line adjacent to the first word line after the applying.

In example embodiments, the method further includes sensing the odd bit line for a read fail to determine whether there is the bit line bridge between the even and odd bit lines.

In example embodiments, the sensing further includes reading a memory cell coupled to the odd bit line and the first word line for the read fail.

In example embodiments, the sensing further includes determining a potential difference between the odd and even bit lines.

In example embodiments, the sensing further includes activating the odd sense amplifier.

In example embodiments, the first changing includes deactivating the odd sense amplifier.

In example embodiments, the second changing includes disabling a pre-charge signal coupled to the odd sense amplifier.

In example embodiments, the second changing further includes disabling the first word line.

In example embodiments, the second changing further includes maintaining the first word line as enabled.

In example embodiments, the applying maintains the pause time such that a leakage path of the odd sense amplifier is cut off.

According to example embodiments, a method of detecting a bit line bridge in a semiconductor memory device includes maintaining a potential difference of an aggressor bit line pair in a sensing state by activating a first bit line sense amplifier coupled to the aggressor bit line pair, pre-charging a victim bit line pair coupled to a second bit line sense amplifier, maintaining a pause time in a state such that a leakage path of the second bit line sense amplifier is cut off, and reading a memory cell connected to the victim bit line after the pause time.

In example embodiments, the reading includes checking the memory cell for a read fail caused by the bit line bridge between a first bit line of the victim bit line pair and a second bit line of the aggressor bit line pair by activating the second bit line sense amplifier.

In example embodiments, the reading further includes determining a potential difference between the aggressor bit line and the victim bit line by deducting a pre-charge voltage from an array internal power voltage or by deducting an array ground power voltage from a pre-charge voltage.

In example embodiments, the pre-charging includes deactivating the second bit line sense amplifier.

In example embodiments, the method further includes changing the victim bit line to a floating state, where the changing includes disabling a first word line coupled to the memory cell and intersecting the victim and aggressor bit lines.

In example embodiments, the changing further includes disabling the first word line.

In example embodiments, the changing further includes maintaining the first word line as enabled.

### BRIEF DESCRIPTION OF THE DRAWINGS

Example embodiments will become more fully understood from the detailed description given herein below and the accompanying drawings in which:

FIG. 1 illustrates a bit line bridge occurring in a general semiconductor memory device in which example embodiments may be implemented;

FIGS. 2 and 3 illustrate timing diagrams for operations of bit line bridge detecting methods according to a related art;

FIG. 4 illustrates an overkill caused by a leakage current of a bit line sense amplifier;

FIG. 5 illustrates a timing diagram for operations in a bit line bridge detecting method according to example embodiments;

FIG. 6 illustrates another timing diagram for operations in the bit line bridge detecting method according to example embodiments;

FIG. 7 is a block diagram of a circuit for a bit line bridge detecting method according to example embodiments;

FIG. 8 illustrates an example of a first block shown in FIG. 7;

FIG. 9 illustrates an example of a second block shown in FIG. 7;

FIG. 10 illustrates an example of a third block shown in FIG. 7;

FIG. 11 illustrates an example of a circuit block included in a row decoder and control block shown in FIG. 7; and

FIG. 12 illustrates an example of a circuit block included in the row decoder and control block shown in FIG. 7.

### DETAILED DESCRIPTION

Example embodiments will now be described more fully hereinafter with reference to the accompanying drawings, in which example embodiments are shown. Example embodiments may, however, be embodied in many different forms and should not be construed as limited to the example embodiments set forth herein. Rather these example embodiments are provided so that this disclosure will be thorough and complete, and will fully convey example embodiments to those skilled in the art. In the drawings, the thicknesses of layers and regions may be exaggerated for clarity. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

Spatially relative terms, such as “beneath,” “below,” “lower,” “above,” “upper,” and the like may be used herein for ease of description to describe the relationship of one component and/or feature to another component and/or feature, or other component(s) and/or feature(s), as illustrated in the drawings. It will be understood that the spatially relative terms are intended to encompass different orientations of the device in use or operation in addition to the orientation depicted in the figures. The figures are intended to depict example embodiments and should not be interpreted to limit the intended scope of the claims. The accompanying figures are not to be considered as drawn to scale unless explicitly noted.

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,” “includes” and/or “including”, when used herein, specify the presence of stated features, integers, steps, operations, elements, and/or components, but do not preclude the presence or addition of one or more other features, integers, steps, operations, elements, components, and/or groups thereof. In this specification, the term “and/or” picks out each individual item as well as all combinations of them.

Example embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which example embodiments belongs. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

Now, in order to more specifically describe example embodiments, example embodiments will be described in detail with reference to the attached drawings. However, example embodiments are not limited to the embodiments described herein, but may be embodied in various forms. In the figures, if a layer is formed on another layer or a substrate, it means that the layer is directly formed on another layer or a substrate, or that a third layer is interposed there between.

When it is determined that a detailed description related to a related known function or configuration may make the purpose of example embodiments unnecessarily ambiguous, the detailed description thereof will be omitted. Also, terms used herein are defined to appropriately describe example embodiments and thus may be changed depending on a user, the intent of an operator, or a custom. Accordingly, the terms must be defined based on the following overall description within this specification. For clarity, the detailed description for a well-known manufacture process and operations of DRAM and its related functional circuits is omitted.

A method of detecting a bit line bridge in a semiconductor memory device according to example embodiments is described as follows, referring to the accompanying drawings.

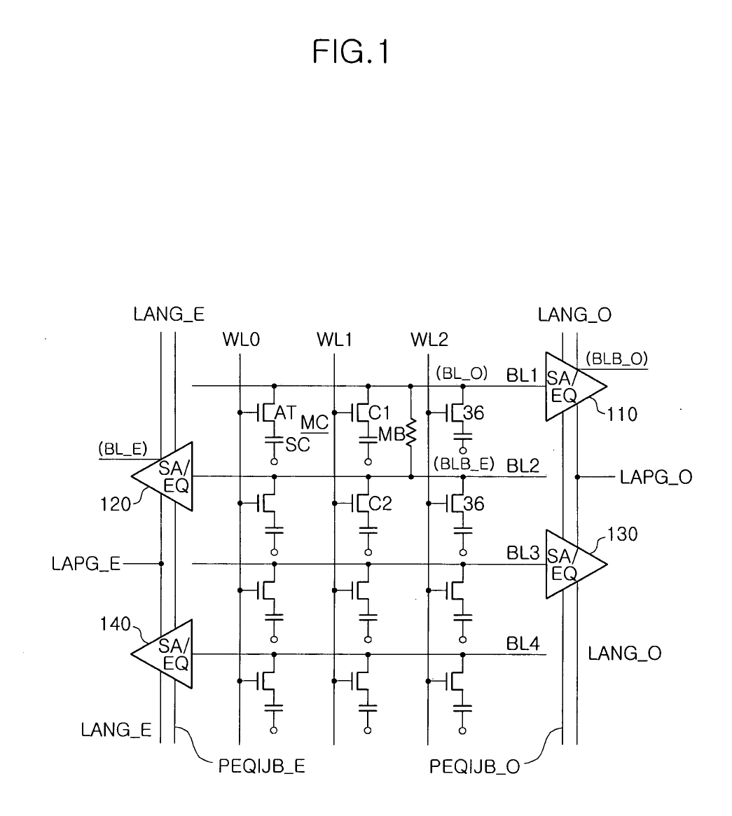

FIG. 1 illustrates a bit line bridge occurring in a general semiconductor memory device in which example embodiments may be implemented.

Referring to FIG. 1, the general semiconductor memory device includes an array of memory cells MC, where each of the memory cells MC includes an access transistor AT and a storage capacitor SC and the memory cells MC are formed at intersections of a plurality of word lines WL0, WL1 and WL2 and a plurality of bit lines BL1, BL2, BL3 and BL4. First and third bit lines BL1 and BL3 are individually coupled to first and third sense amplifiers 110 and 130, respectively, and second and fourth bit lines BL2 and BL4 are individually coupled to second and fourth sense amplifiers 120 and 140, respectively. For example, in FIG. 1, odd bit lines, which include the first and third bit lines BL1 and BL3, are sensed and amplified by the coupled odd sense amplifiers, which include the first and third sense amplifiers 110 and 130, arranged in a right side of a memory cell array; and even bit lines, which include the second and fourth bit lines BL2 and BL4, are sensed and amplified by the coupled even sense amplifiers, which include the second and fourth sense amplifiers 120 and 140, arrayed in a left side of the memory cell array.

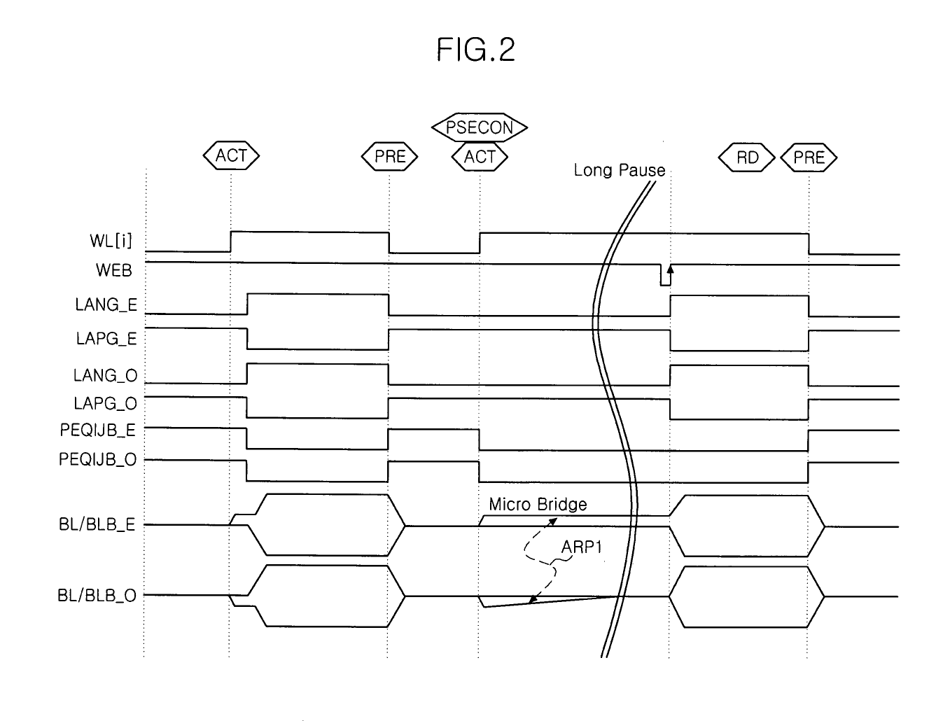

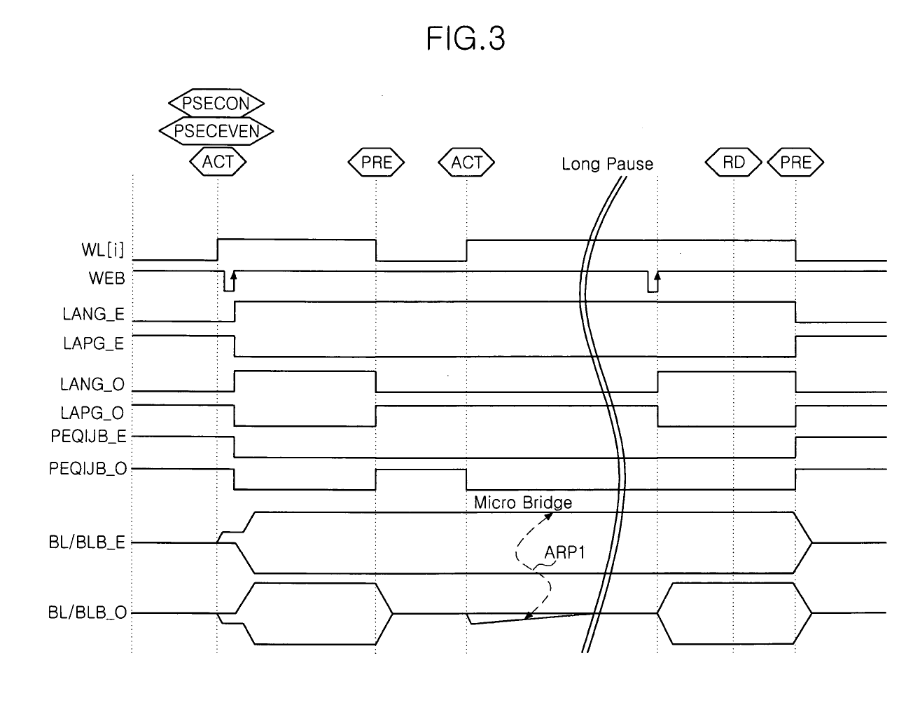

For example, when a bit line micro bridge MB between bit lines BL1 and BL2 occurs between memory cells C1 and C2 coupled with a word line WL1, detecting methods according to a related art may be used to detect the micro bridge, as shown in further detail below in FIGS. 2 and 3. In FIG. 1, the odd sense amplifiers 110 and 130 are driven by a first power signal LAPG_O and a first ground signal LANG_O, and the even sense amplifiers 120 and 140 are driven by a second power signal LAPG_E and a second ground signal LANG_E.

For the sake of convenience, the odd sense amplifiers 110 and 130 and the even sense amplifiers 120 and 140 are described together as an equalizing unit, with the odd sense amplifiers 110 and 130 being coupled to an odd equalization signal PEQIJB_O and the even sense amplifiers 120 and 140 being coupled to an even equalization signal PEQIJB_E.

FIGS. 2 and 3 illustrate timing diagrams for operations of bit line bridge detecting methods according to a related art.

FIG. 2 provides a test method performed to detect a micro bridge between bit lines BL as shown in FIG. 1. The test method shown in FIG. 2 is called herein a paused sensing enable control (PSEC).

According to the detecting method of FIG. 2, a relatively long pause time is provided after an active command ACT is applied and before a sensing operation begins. Referring to FIGS. 1 and 2, a bit line BL1 is connected to a memory cell C1 storing data “1” and a bit line BL2 is connected to a memory cell C2 storing data “0.” The bit lines BL1 and the BL2 are in a charge sharing state after the word line WL1 is activated in response to the ACT command and before the sensing operation begins. For example, the first bit line BL1 (BL_O of FIG. 2), referred to here as a victim bit line, in the charge sharing state initially precharges the second bit line BL2, referred to here as an aggressor bit line, to a precharged state having a voltage level VBL. Then, a potential difference corresponding to a charge sharing voltage between adjacent bit lines BL1 and BL2 is generated, and when a micro bridge occurs, a charge sharing voltage level of the victim bit line BL1 (BL_O of FIG. 2) becomes the voltage level VBL by an influence of bit line BL2, as illustrated by reference character ARP1 in FIG. 2. A relatively long pause time is provided after the potential difference is generated between the bit lines BL1 and BL2. As the long pause time passes, the charge sharing voltage of BL1 decreases and data stored in the memory cell C2 may at least be partially damaged or lost due to an effect of the micro bridge connected with the bit line BL2. Afterwards, the sensing operation begins when a WEB signal toggles after the relatively long pause time passes and then a read operation begins in response to the read command RD

Thus, the method of FIG. 2 employs a principle that the voltage level of the victim bit line becomes the voltage level VBL (or the voltage level of the aggressor bit line) when a micro bridge is generated, thus generating a fail in a data read. However, in the test method of FIG. 2, because a potential difference between the bit lines BLs being tested in the charge sharing state is relatively low, the pause time provided is relatively long. Therefore, the paused sensing enable control (PSEC) in the method of FIG. 2 is not applicable or practical for use during mass production. As a result, a faster or accelerated test method is required (herein referred to as an “acceleration test”).

To resolve the issue of the relatively long pause time of the test method of FIG. 2, a distributed PSEC (dPSEC) method has been developed, as shown in FIG. 3. In the method of FIG. 3, a state of the adjacent aggressor bit line BL2 is maintained at a sensing level, while the victim bit line BL1 has a charge sharing state, and then a long pause time is provided. However, in this case, because a potential difference between the bit line BL_O and BLB_E having a micro bridge is greater, as illustrated by reference character ARP1 in FIG. 3, the long pause time of FIG. 3 is of a shorter time period relative to that of FIG. 2. Accordingly, a time taken in inverting a charge sharing voltage of the victim bit line BL_O is reduced relative to that of FIG. 2.

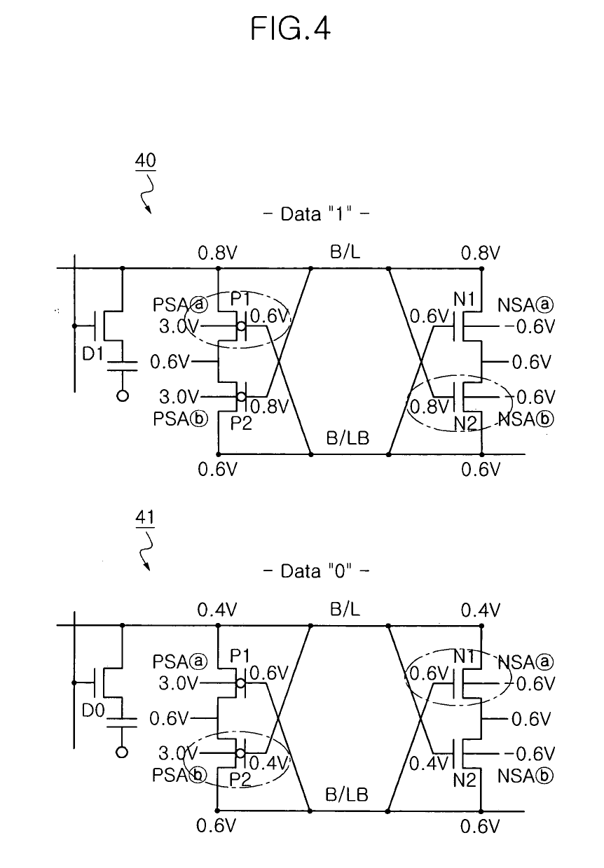

However, the two methods referred to in FIGS. 2 and 3 still have an issue that remains unresolved. When the bit line pair BL/BLB is in a charge sharing voltage state, the bit line pair BL/BLB develops a bias condition, such as shown an in FIG. 4 below, which causes an overkill problem in the test procedure.

FIG. 4 illustrates the overkill problem caused by a leakage current of a bit line sense amplifier (“BLSA”). In FIG. 4, a reference number 40 indicates a bias voltage in a charge sharing state provided to P-type sense amplifiers P1, P2 and N-type sense amplifiers N1, N2 when a memory cell D1 stores data “1”, and a reference number 41 indicates a bias voltage in a charge sharing state provided to P-type sense amplifiers P1, P2 and N-type sense amplifiers N1, N2 when memory cell D0 stores data “0”.

Such bias conditions as shown in FIG. 4 also have an issue to be resolved in that a gate-source voltage Vgs is generated at bit lines B/L and B/LB corresponding to the charge sharing voltage level even without a bridge between adjacent bit lines (BL1 and BL2 of FIG. 1), and thus a leakage current is caused. For example, as shown at reference 40, when a cell D1 is in the charge sharing state the PMOS transistor P1 constituting a P-type sense amplifier PSA is slightly turned on due to the Vgs −0.2 V and an NMOS transistor N2 constituting an N-type sense amplifier NSA is slightly turned on due to the Vgs 0.2 V. However, as shown at reference 41, when a cell D0 is in the charge sharing state, the NMOS transistor N1 constituting an N-type sense amplifier NSA is slightly turned on due to the Vgs 0.2 V and a PMOS transistor P2 constituting a P-type sense amplifier PSA is slightly turned on due to the Vgs −0.2 V. So, a leakage current of the slightly turned on transistors in the bit sense amplifier BLSA affects the charge sharing voltage of the bit lines. In such bridge detecting methods according to a related art, effects of leakage of the bit line sense amplifier BLSA on the charge sharing voltage may become more serious under an influence of the bit line bridge.

Therefore, it may be difficult to detect a micro bridge only caused by a leakage of the bit line sense amplifier BLSA and thus difficult to completely disregard the overkill during the detection methods of FIGS. 2 and 3.

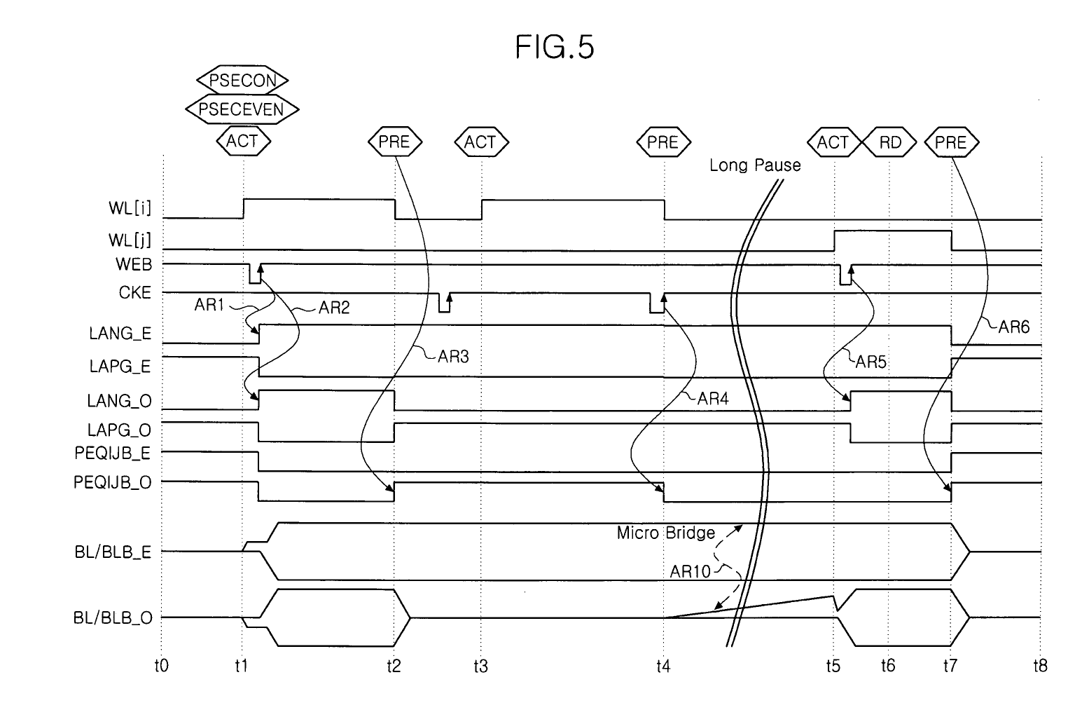

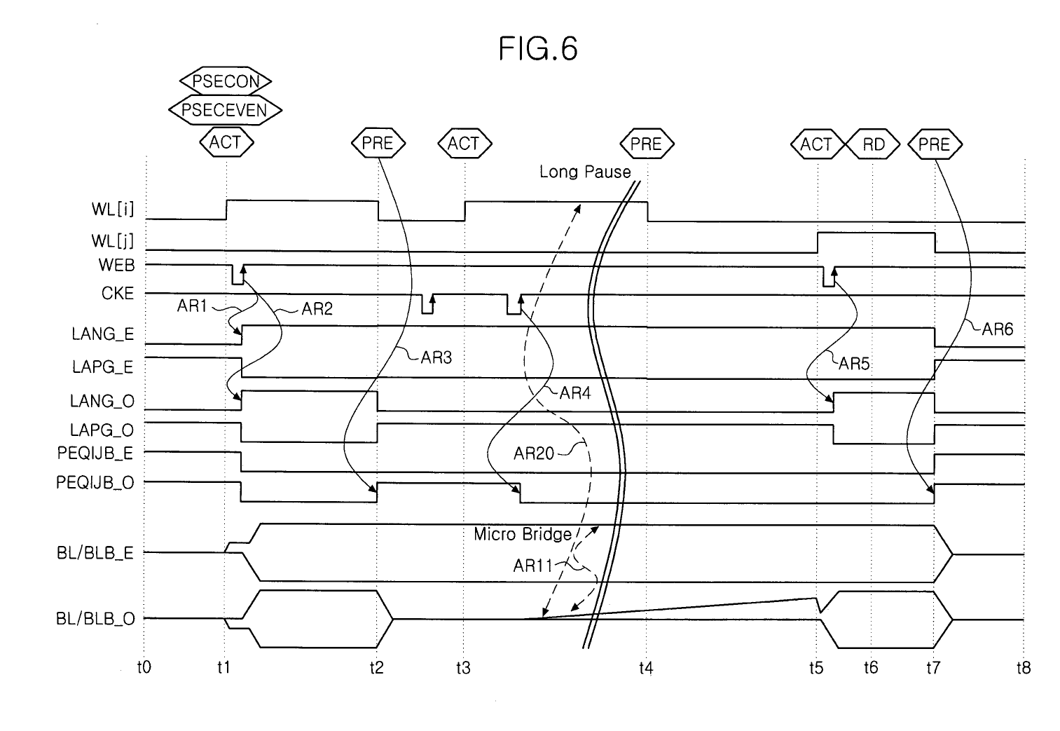

Accordingly, in example embodiments, a detection method such as in FIGS. 5 and 6, is provided to solve or reduce effects of even an overkill based on a leakage of the BLSA caused in the detection methods of the related art described above, including the reduction of test time.

To prevent or reduce the overkill caused by the leakage of BLSA, one or more example embodiments test in a bias condition where a leakage of the bit line sense amplifier BLSA does not occur or is reduced.

According to an example embodiment, in a method to prevent or reduce a leakage of the bit line sense amplifier BLSA, a relatively long pause time is given at an initial precharge state, instead of providing the long pause time in the charge sharing state of the bit lines. For example, as an adjacent aggressor bit line (such as BL_E of FIG. 1) leaves a sensing state, a voltage level of a victim bit line (such as BL_O of FIG. 1) is precharged to a VBL voltage level and then a relatively long pause time is provided. Then, voltage levels Vgs and Vds of the corresponding BLSA (110 of FIG. 1) become 0 V and thus a leakage path is not formed. On the other hand, a potential difference of adjacent bit lines BLs (BL1 and BL2 of FIG. 1) becomes ‘a first sensing power voltage—VBL’ or ‘VBL—a second sensing power voltage, thus creating a condition for an acceleration test. Such a test method is called herein for a descriptive convenience an enhanced PSEC (ePSEC) test method.

FIG. 5 illustrates a timing diagram for operations in a bit line bridge detecting method according to example embodiments. FIG. 6 illustrates another timing diagram for operations in a bit line bridge detecting method according to example embodiments.

Timings for operations in FIG. 5 are first described as follows.

When a PSECEVEN test MRS is entered in a PSECON [=PSEC Test Enable MRS] mode as shown at a time point t1, even bit lines (BL2 and BL4 of FIG. 1) become aggressor lines, and odd bit lines (BL1 and BL3 of FIG. 1) become victim bit lines. The victim bit line indicates herein a bit line as a test target, and the aggressor bit line indicates a line hurting or interfering with the victim bit line. In a PSECON mode, a sensing operation of bit line BL is controlled by a WEB pin and an active command ACT, and an equalizing operation of the bit line BL is controlled by a CKE pin and a precharge command PRE. Word line WL[i] corresponding to word line WL1 of FIG. 1 is activated in “PSECON+PSECEVEN” mode and the WEB pin is toggled. Sense amplifiers 110 through 140 shown in FIG. 1 are activated in response to sense amplifier enable signals LANG_E, LAPG_E, LANG_O and LAPG_O generated along arrows of reference characters AR1 and AR2 shown in the drawing. Then, even/odd bit line pairs BL/BLB_E and BL/BLB_O enter a sensing state, as illustrated in the timings of FIG. 5. This corresponds to a timing of operation between a time point t1 and a time point t2 of FIG. 5.

Subsequently, when a precharge command PRE is applied at the time point t2 as shown in reference character AR3, the even bit line pair BL/BLB_E is continuously maintained as the sensing state in the PSECEVEN mode and odd bit line pair BL/BLB_O is changed to a precharge state. Then, when the active command ACT is again applied at a time point t3 after CKE is toggled, a voltage level of the odd bit line pair BL/BLB_O continuously maintains the precharge state even when WL[i] is in an enable state in response to the active command ACT. When CKE is again toggled at a time point t4, the even bit line pair is still in the sensing state, and a precharge operation for the odd bit line pair BL1 is disabled in response to PEQIJB_O, as shown in a reference character AR4. Thus the odd bit line pair BL/BLB_O is changed in to a floating state and not the sensing state or the precharge state, starting at the precharge level. As described above, in the floating state after the applied precharge disable command PRE, a relatively long pause time is provided and then an active command ACT is applied at a time point t5 to detect whether a micro bridge exists.

For example, when a micro bridge exists between adjacent bit lines BL, e.g., between even bit line BL2 and odd bit line BL1 in FIG. 1, victim bit line pair BL/BLB_O is changed from the VBL voltage level to an other voltage level, as shown by reference character AR10. In this case, a memory cell corresponding to WL[i] has been already precharged to the VBL voltage level and thus storage data has been lost. Thus, in applying a read (RD) command, another word line WL[j] of the same bit line (BL1 of FIG. 1) is enabled, thereby reading data. The word line WL[j] may correspond to word line WL2 in FIG. 1, and the adjacent memory cell may correspond to a memory cell 36 coupled to an intersection of bit line BL1 and word line WL2. The detection operation of a bit line micro bridge is completed at a time point t7 when the precharge command PRE is enabled as shown by reference character AR6.

As described above, for example, when the victim bit line pair BL/BLB_O is changed to the other voltage level due to the existence of a micro bridge between the adjacent bit lines BLs (for example, BL1 and BL2), it may be difficult or impossible to invert such a changed voltage level with a relatively weak memory cell charge, thus causing a read fail. Thus, according to an example embodiment, when the read fail occurs, a read fail caused purely or only by the micro bridge is detected relatively quickly and excludes a read fail error detection caused by a leakage current of bit line sense amplifier between the bit lines BL not sharing the same sense amplifier. A characteristic to be considered in FIG. 5 is that a memory cell detected as a read fail is not the actual memory cell having the failed occurrence, but instead the failed memory cell is an adjacent memory cell thereto.

The detection method with operation timings of FIG. 5 includes the following operations.

The detection method of FIG. 5 includes maintaining an even bit line pair BL/BLB_E and an odd bit line pair BL/BLB_O at a sensing state by enabling a first word line (WLi of FIG. 5) in response to an active command ACT in a test mode and activating odd and even sense amplifiers (110 and 120 of FIG. 1); inactivating the odd sense amplifier 110 while maintaining the sensing state of the even bit line pair BL/BLB_E and thus precharging the odd bit line pair BL/BLB_O to a precharge level; continuously keeping the precharge state of the odd bit line pair BL/BLB_O even when the first word line (WLi of FIG. 5) is enabled by the applied active command ACT, and then maintaining a floating state of the odd bit line pair BL/BLB_O by disabling a precharge signal PEQIJB_O for the odd bit line pair and the first word line (WLi of FIG. 5); and applying a relatively long pause time of approximately ten micro seconds for a test in the floating state and then enabling a second word line (WLj of FIG. 5) adjacent to the first word line (WLi of FIG. 5), and sensing the odd bit line pair BL/BLB_O as a test target and thus checking as to whether a read fail occurs owing to a micro bridge between odd and even bit lines BL1 and BL2.

The odd and even sense amplifiers 110 and 120 individually include an n-type sense amplifier including NMOS transistors and a p-type sense amplifier including PMOS transistors as described above referring to FIG. 4. The sensing and precharge states are controlled by a toggle number of the control pin CKE.

FIG. 6 illustrates another timing diagram for operations in the bit line bridge detecting method according to example embodiments.

Timings of operations referred to in FIG. 6 are generally similar to that of FIG. 5, except for providing a relatively long pause time in a state that the word line WL[i] has been activated, as illustrated in a reference character AR11. For example, in the detection method referred to in FIG. 6, a micro bridge between bit lines may be detected. However, a voltage level of the victim bit line pair BL/BLB_O may also be affected by a memory cell bridge. Thus, the method of FIG. 6 also detects the memory cell bridge. For example, in FIG. 5, a relatively long pause time is provided in the state that WL[i] has been inactivated and thus only a read fail caused by bit line BL bridge is detected, but in FIG. 6, a read fail caused by a memory cell bridge can be also detected. Accordingly, the method ePSEC2 of FIG. 6 may an appropriate method for the test mode in a mass production.

The detection method based on timings of operations in FIG. 6 includes the following operations.

The detection method of FIG. 6 includes maintaining an even bit line pair BL/BLB_E and an odd bit line pair BL/BLB_O as a sensing state by enabling a first word line WL[i] in response to an active command ACT in a test mode and activating odd and even sense amplifiers 110 and 120; inactivating the odd sense amplifier 110 while maintaining the sensing state of the even bit line pair BL/BLB_E and thus precharging the odd bit line pair BL/BLB_O to a precharge level; continuously keeping the precharge state of the odd bit line pair BL/BLB_O even when the first word line WL[i] is enabled by the applied active command ACT, and then maintaining a floating state of the odd bit line pair BL/BLB_O in an enable maintenance state of the first word line WL[i] by disabling a precharge signal PEQIJB_O for the odd bit line pair; and applying a pause time for a test in the floating state and then enabling a second word line WL[j] adjacent to the first word line WL[i], and sensing the odd bit line pair BL/BLB_O as a test target and thus checking as to whether a read fail occurs owing to cell bridge and micro bridge between odd and even bit lines BL1 and BL2.

On the other hand, the ePSEC1 method described in FIG. 5 may be useful in an analysis to clarify a cause of read failure. Either of the methods ePSEC1 and ePSEC2 described with respect to FIGS. 5 and 6, according to example embodiments may be interchangeably implemented in a same logic circuit by changing test timings.

An example of logic circuit to realize the detection methods of FIGS. 5 and 6 is described as follows. The following described logic circuit is provided as an example, and may be realized in other configurations as well.

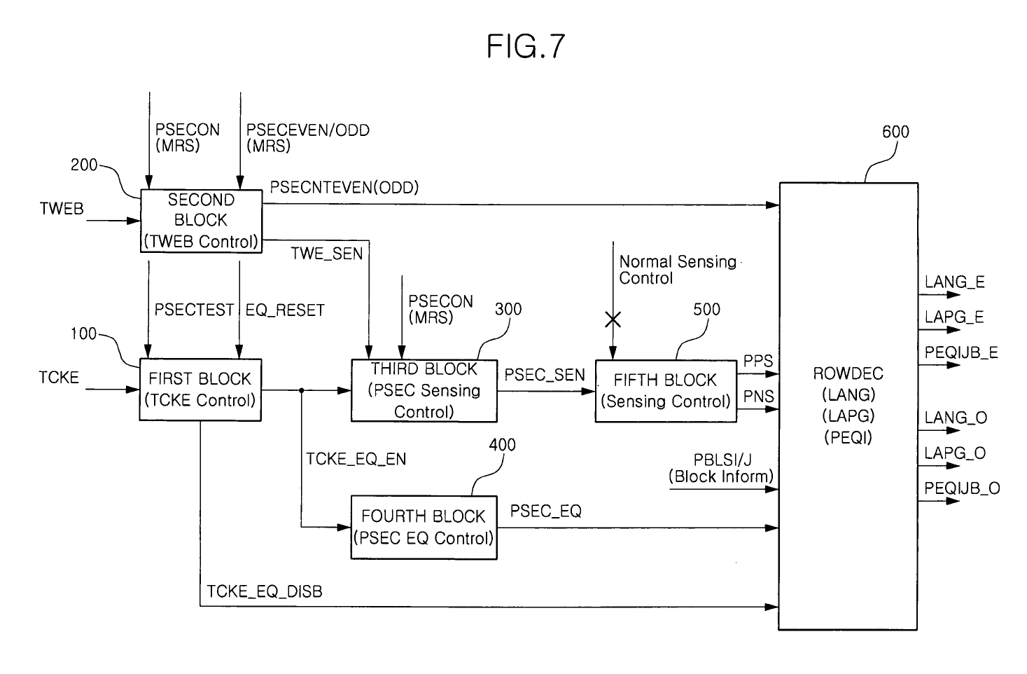

FIG. 7 is a block diagram of a circuit for a bit line bridge detecting method according to example embodiments. In FIG. 7, a first block 100 generates an equalization enable signal TCKE_EQ_EN for controlling precharge and equalization operations of a bit line. A TCKE signal, like the CKE waveform shown in FIG. 5 or 6, and a PSECTEST signal and a EQ_RESET signal output from a second block 200 are applied to the first block 100. The TCKE signal is applied externally through a CKE pin. Although in example embodiments, the TCKE signal is applied through the CKE pin, the TCKE signal may be applied through other pins as well. An equalization enable or disable operation of the victim bit line, such as the first bit line BL1 (BL_O of FIG. 5), is performed by a toggling of the TCKE signal and a precharge command (PRE of FIG. 5). For example, when the TCKE signal is toggled once after a time point t2 of FIG. 5, the first block 100 activates the equalization enable signal TCKE_EQ_EN, and when the TCKE signal is toggled once more at a time point of t4 shown in FIG. 5, the first block 100 activates the equalization disable signal TCKE_EQ_DISB.

The second block 200 generates a sensing enable signal TWE_SEN, an even or odd block sensing decision signal PSECNTEVEN/PSECNTODD, the test start signal PSECTEST, and the equalization reset signal EQ_RESET for controlling bit line sensing operations. A TWEB signal, such as the WEB waveform shown in FIG. 5 or 6, a test mode on-signal PSECON, and an even or odd block external selection signal PSECEVEN/ODD are applied to the second block 200. The TWEB signal is applied externally through a WEB pin. Although in example embodiments, the TWEB signal is applied through WEB pin, the TWEB signal may be applied through other pins as well. The test mode on-signal PSECON, and the even or odd block external selection signal PSECEVEN/ODD may be applied as a mode register set (MRS) signal. For example, when a precharge command PRE is applied at time points of t2 and t4 shown in FIGS. 5 and 6, an aggressor bit line, such as the second bit line BL2 (BLB_E in FIGS. 5 and 6), keeps a sensing state obtained from the second block 200 that responds to the toggling of the TWEB signal.

A third block 300 receives the sensing enable signal TWE_SEN from the second block 200 and the equalization enable signal TCKE_EQ_EN from the first block 100, and then generates a PSEC sensing control signal PSEC_SEN. When a normal sensing path is blocked, the PSEC_SEN is valid as an input of a fifth block 500. The test mode on-signal PSECON may be applied as an MRS signal to the third block 300.

A fourth block 400 receives the equalization enable signal TCKE_EQ_EN and generates a bit line equalization control signal PSEC_EQ. The fourth block 400 may be implemented as a delay chain, and generates the bit line equalization control signal PSEC_EQ by bypassing or delaying the equalization enable signal TCKE_EQ_EN. Therefore, the victim bit line, such as the first bit line BL1 (BL_O in FIGS. 5 and 6), continuously maintains a precharge and equalization state at time point t3 of FIGS. 5 and 6.

A fifth block 500 performs a blocking for a sensing control signal of a normal path when the test mode on-signal PSECON is activated, and receives the PSEC_SEN signal output from the third block 300 and then generates p-type and n-type sense amplifier control signals PPS/PNS necessary for controlling p-type and n-type sense amplifiers such as the sense amplifiers 110 and 120 of FIG. 1. The fifth block 500 functions as a selector selecting one of two inputs according to an output level of the test mode on-signal PSECON.

In a test mode of detecting the bit line bridge, the even or odd block sensing decision signal PSECNTEVEN/ODD output from the second block 200, the p-type and n-type sense amplifier control signals PPS/PNS output from the fifth block 500, the bit line equalization control signal PSEC_EQ output from the fourth block 400, the equalization disable signal TCKE_EQ_DISB output from the first block 100, and a block selection signal PBLSI/J are applied to a ROWDEC 600 serving as a row decoder and control block. In response to the above signals, the ROWDEC 600 generates the following signals (as shown in FIGS. 5 and 6), so as to independently perform a precharge and equalization operation, sensing operation and row decoding operation for a detection of the bit line bridge: an even block n-type sense amplifier drive signal LANG_E, an even block p-type sense amplifier drive signal LAPG_E, an even block equalization signal PEQIJB_E, an odd block n-type sense amplifier drive signal LANG_O, an odd block p-type sense amplifier drive signal LAPG_O, and an odd block equalization signal PEQIJB_O.

As a result, when a PSECON mode starts by an applied MRS signal, a sensing path of a normal active state becomes blocked, and the second block 200 receiving the TWEB (WEB) signal generates the PSECNTEVEN/ODD and TWE_SEN signals. Accordingly, a sensing for the even/odd block Even/Odd BLK can be separately controlled by the ROWDEC 600. Further, during the PSECON mode, the equalizing path of a normal active state is blocked and the first block 100 receiving the TCKE (CKE) signal generates the equalization enable signal TCKE_EQ_EN and the equalizing disable signal TCKE_EQ_DISB. Therefore, an equalization for the even/odd block can be separately controlled by the ROWDEC 600. One even/odd block herein indicates all memory cells coupled to the same even/odd bit line.

In performing a bridge detection as illustrated in FIG. 5 or 6 by using the configuration of circuit shown in FIG. 7, an overkill factor caused by leakage current of a bit line sense amplifier in a bridge detection between bit lines or memory cells is removed or reduced.

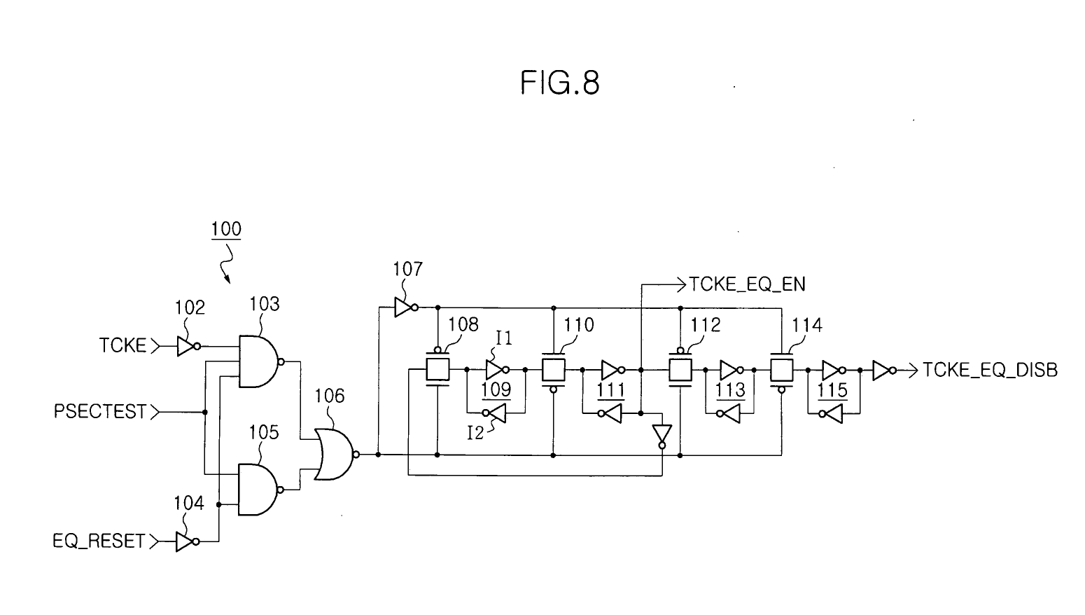

FIGS. 8 to 12 are circuit diagrams illustrating examples of circuit blocks shown in FIG. 7.

FIG. 8 illustrates an example of the first block 100 shown in FIG. 7. In FIG. 8, the first block 100 includes inverters 102, 104 and 107, NAND gates 103 and 105, NOR gate 106, transmission gates 108, 110, 112 and 114, and inverter latches 109, 111, 113 and 115.

Referring to FIG. 8, TCKE signal is applied through the inverter 102 to the NAND gate 103, the test start signal PSECTEST is applied in common to the NAND gates 103 and 105, and the equalization reset signal EQ_RESET is applied through the inverter 104 to the NAND gates 103 and 105. The NOR gate 106 receives outputs of the NAND gates 103 and 105, and generates a NOR response. The output of the NOR gate 106, and an output of the inverter 107 inverting the output of the NOR gate 106, are used as a drive signal of driving transmission gates 108, 110, 112 and 114. The transmission gates 110 and 114 are turned on when the output of the NOR gate 106 has a logic low level, and the transmission gates 108 and 112 are turned on when the output of the NOR gate 106 has a logic high level. Input terminals of the inverter latches 109 and 113 respectively have a reset state of a low level.

The TCKE signal, such as the waveform CKE of FIG. 5, is maintained as a logic high level until toggled between time point t2 and t3 of FIG. 5. Thus, when the test start signal PSECTEST has a logic high level and the equalization reset signal EQ_RESET has a logic low level, an output of the NAND gate 103 becomes a logic high level. In this case, an output of the NAND gate 105 has a logic low level, and therefore an output of the NOR gate 106 also becomes a logic low level. As a result, the transmission gates 110 and 114 are turned on. A logic high level output of an inverter latch 109 is transferred to an input terminal of an inverter latch 111 through the transmission gate 110, and a logic high level output of an inverter latch 113 is transferred to an input terminal of an inverter latch 115 through the transmission gate 114. Accordingly, the equalization enable signal TCKE_EQ_EN is maintained at a low state “L” in a reset state. Before the TCKE signal is toggled, the equalization disable signal TCKE_EQ_DISB inverted and outputted after passing through the inverter latch 115 is maintained at a high state “H”. This state is a reset logic state provided before a toggling.

When a level of the TCKE signal becomes a logic low level in between time points t2 and t3 to begin the toggling for the TCKE signal, an output of the NAND gate 103 becomes a logic low level. Then, an output of the NOR gate 106 becomes a logic high level, and the transmission gates 108 and 112 are turned on. The input terminal of the inverter latch 109 becomes a high level, and a logic low output of inverter latch 111 is transferred to an input terminal of inverter latch 113 through the transmission gate 112. An output terminal of the inverter latch 109 becomes a logic high level, and an output terminal of the inverter latch 113 becomes a logic high level, but the equalization enable signal TCKE_EQ_EN is still maintained at a low state “L”, and the equalization disable signal TCKE_EQ_DISB is still maintained at a high state “H” since the transmission gates 110 and 114 have a turn-off state.

When a toggling of the TCKE signal, such as the waveform CKE of FIG. 5, from a low level to a high level is performed once in between time points t2 and t3 of FIG. 5 to finish the toggling, an output of the NAND gate 103 is changed to a logic high state. In this case, the test start signal PSECTEST (or PSECON) has a logic high level and the equalization reset signal EQ_RESET has a logic low level. As an output of the NAND gate 105 has a logic low level, an output of the NOR gate 106 becomes a logic low level and the transmission gates 110 and 114 are turned on. A logic low output of the inverter latch 109 is transferred through the transmission gate 110 to the input terminal of the inverter latch 111, and a logic high output of the inverter latch 113 is transferred through the transmission gate 114 to an input terminal of the inverter latch 115. Thus, the equalization enable signal TCKE_EQ_EN is changed to a high state “H”, and the equalization disable signal TCKE_EQ_DISB is maintained at the logic high “H” level intact without change.

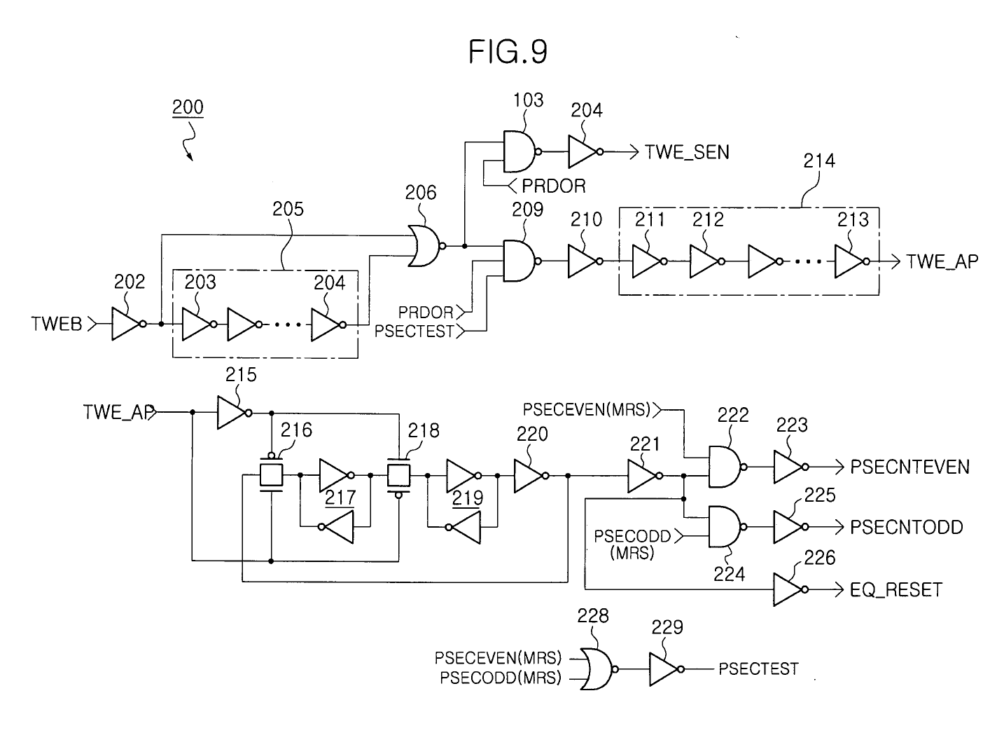

The TCKE signal having been returned to the high level is transited to a low level immediately before a time point t4 of FIG. 5 and then increases to a high level. Thus, when a toggling is again performed, the same operation as the above description is performed several times. Accordingly, the equalization enable signal TCKE_EQ_EN is again changed into the low state “L”, and the equalization disable signal TCKE_EQ_DISB is again changed into the low state “L”. The test start signal PSECTEST applied with reference to FIG. 8 is used as an enable signal to validate an input path of the TCKE signal in a test mode, and is generated in a circuit of FIG. 9. Further, the equalization reset signal EQ_RESET is used as a flip-flop reset signal.

In FIG. 8, the output of the NOR gate 106 functions as a clock input of a T-flip-flop, and the transmission gates 108, 110, 112 and 114, and the inverter latches 109, 111, 113 and 115 operate as a T-flip-flop type.

FIG. 9 illustrates an example of second block 200 shown in FIG. 7. In FIG. 9, the second block 200 includes inverter 202, delay 205, NOR gate 206, NAND gates 103 and 209, inverters 204 and 210, delay 214, inverter 215, transmission gates 216 and 218, inverter latches 217 and 219, inverters 220 and 221, NAND gates 222 and 224, inverters 223, 225 and 226, NOR gate 228, and inverter 229.

Referring to FIG. 9, the TWEB signal, such as the WEB waveform shown in FIG. 5, is applied through the inverter 202. A short pulse output through the inverter 202 and a short pulse delayed through the delay 205 are NOR-gated by the NOR gate 206. The NAND gate 103 receives an output of the NOR gate 206 and a bank active OR-ing signal PRDOR activated when a memory bank is activated, and then generates a NAND response. The inverter 204 inverting an output of the NAND gate 103 outputs the sensing enable signal TWE_SEN. When the TWEB signal rises to a high level, an output of the NOR gate 206 becomes a high level, thus the sensing enable signal TWE_SEN is generated as a logic high level in response to a rising edge of the TWEB signal. Also, the NAND gate 209 receives the bank active OR-ing signal PRDOR, the test start signal PSECTEST, and an output of the NOR gate 206, and generates a NAND response. An output of the NAND gate 209 is inverted by the inverter 210, and then is generated as a sensing auto pulse TWE_AP signal through the delay 214. The sensing auto pulse TWE_AP signal and its inverted signal are used as a drive signal of driving the transmission gates 216 and 218. The transmission gate 216 is turned on when the sensing auto pulse TWE_AP signal has a logic high level, and the transmission gate 218 is turned on when the sensing auto pulse TWE_AP signal has a logic low level. At this time, an input terminal of the inverter latch 217 has a reset state of a low level. When the transmission gate 216 is turned on, an output of the inverter 220 is transferred to the inverter latch 217 through the transmission gate 216, and when the transmission gate 218 is turned on, an output of the inverter latch 217 is transferred to the inverter latch 219. An output of the inverter 220 is inverted through the inverter 221 and then is applied to the NAND gate 222. The NAND gate 222 receives the even block external selection signal PSECEVEN applied as the MRS signal and an output of the inverter 221, and generates a NAND response. The NAND response is inverted through the inverter 223, and is output as the even block sensing decision signal PSECNTEVEN. The NAND gate 224 receives the odd block external selection signal PSECODD applied as the MRS signal and an output of the inverter 221, and generates a NAND response. The NAND response is inverted through the inverter 225 and is output as the odd block sensing decision signal PSECNTODD. The equalization reset signal EQ_RESET is generated by the inverter 226 inverting an output of the inverter 221. Meanwhile, as just any one of the even block external selection signal PSECEVEN and the odd block external selection signal PSECODD is provided as a high level, an output of the NOR gate 228 becomes a logic low level, and an output of the inverter 229 becomes a high level. Therefore, the test start signal PSECTEST output through the inverter 229 is generated as a high level in the test mode. Further, when the even block sensing decision signal PSECNTEVEN is activated as a high level, the odd block sensing decision signal PSECNTODD is inactivated as a low level.

Accordingly, in the PSECON mode, the even block external selection signal PSECEVEN is provided as a high level and the PSECNTEVEN is output as a high state: “H” level when the TWEB signal is toggled at a time point t1 of FIG. 5. Further, when in this state, the TWEB signal is again toggled at a time point t5 of FIG. 5, the PSECNTEVEN is output as a low state “L” level. Similar to FIG. 8, whenever a clock, sensing auto pulse TWE_AP, is toggled by an operation type of T-flip-flop, and levels of outputs of the even block external selection signal PSECEVEN are alternately changed. As shown in FIG. 9, a circuit of FIG. 9 including a plurality of logic gates performs a function of continuously maintaining a sensing state of the aggressor bit line by the PSECEVEN/PSECODD provided as the MRS and the TWEB signal controlled for a toggling.

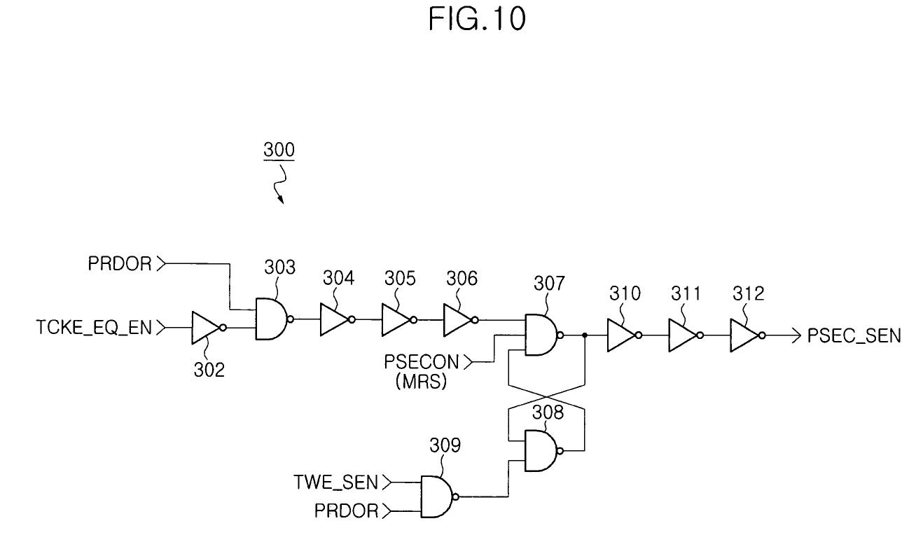

FIG. 10 illustrates an example of the third block 300 shown in FIG. 7. In FIG. 10, the circuit block 300 includes inverter 302, NAND gate 303, inverters 304, 305 and 306, NAND gates 307, 308 and 309, and inverters 310, 311 and 312. The third block 300 generates the PSEC sensing control signal PSEC_SEN in response to the sensing enable signal TWE_SEN when the test mode on-signal PSECON is applied as a high level.

In FIG. 10, the NAND gate 309 receives the sensing enable signal TWE_SEN applied from the second block 200, and the bank active OR-ing signal PRDOR, and generates a NAND response. An output of the NAND gate 307 among the NAND gates 307 and 308 constituting an SR latch is decided by an output of the NAND gate 309. The output of the NAND gate 307 is inverted through the inverters 310, 311 and 312, and then is output as the PSEC sensing control signal PSEC_SEN. After a time point t1 of FIG. 5, the sensing enable signal TWE_SEN and the bank active OR-ing signal PRDOR all become a high level. Thus, an output of the NAND gate 309 becomes a low level. Accordingly, an output of the NAND gate 307 becomes a low state “L”, and then the PSEC sensing control signal PSEC_SEN output through the inverter 312 is generated as a high level.

According to example embodiments, the test mode on-signal PSECON is applied as one of the inputs of the NAND gate 307 to provide a valid output of the PSEC sensing control signal PSEC_SEN when the test mode on-signal PSECON has a high level. Similarly, when the bank active OR-ing signal PRDOR is not a high level, circuit devices are employed such that the equalization enable signal TCKE_EQ_EN becomes blocked. Examples of such employed circuit devices are the inverter 302 inverting the equalization enable signal TCKE_EQ_EN output from the first block 100, the NAND gate 303 for receiving an output of the inverter 302 through one input terminal and receiving the bank active OR-ing signal PRDOR through another input terminal and thus generating a NAND response, and the inverters 304, 305 and 306 coupled in sequence to the output terminal of the NAND gate 303. As a result, when the bank active OR-ing signal PRDOR has a low level, one input of the NAND gate 307 becomes a low level and thus an output of the PSEC sensing control signal PSEC_SEN becomes invalid.

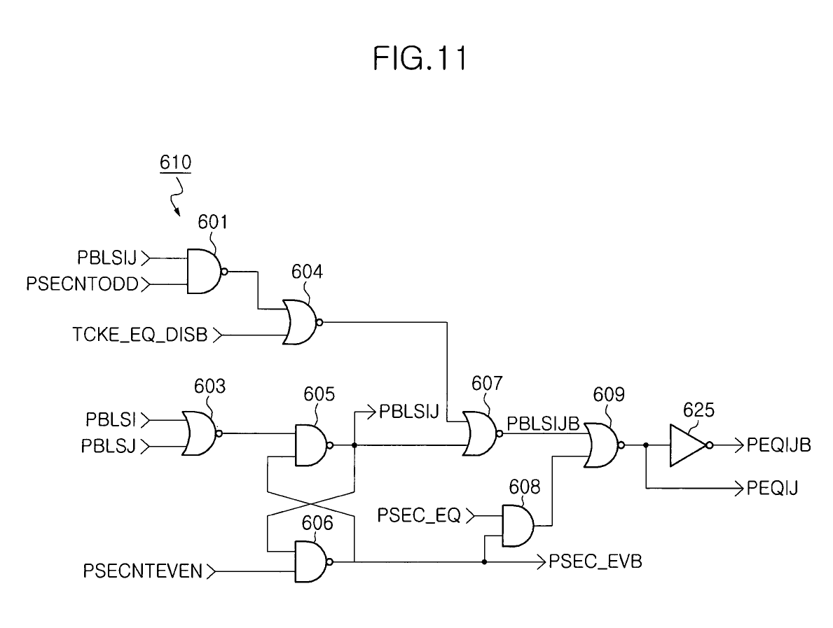

FIG. 11 illustrates an example of a circuit block 610 included in a row decoder and control block 600 shown in FIG. 7. The circuit block 610 generates block equalization signals PEQIJ and PEQIJB necessary for controlling a bit line equalization of each block by using the equalization disable signal TCKE_EQ_DISB generated in the first block 100 of FIG. 7, the even or odd block sensing decision signal PSECNTEVEN/ODD output from the second block 200, the bit line equalization control signal PSEC_EQ output from the fourth block 400, and the block selection signal PBLSI/PBLSJ. The circuit block 610 of FIG. 11 provides a circuit related to an even block and a connection configuration among a plurality of logic gates 601, 603, 604-609 and 625.

In FIG. 11, a NAND gate 601 receives a block selection composition signal PBLSIJ generated in an output terminal of NAND gate 605 and the odd block sensing decision signal PSECNTODD, and generates a NAND response. A NOR gate 604 receives an output of the NAND gate 601 and the equalization disable signal TCKE_EQ_DISB, and generates a NOR response. A NOR gate 603 receives the block selection signals PBLSI and PBLSJ and generates a NOR response. NAND gates 605 and 606 constituting an SR latch receive an output of the NOR gate 603 and the even block sensing decision signal PSECNTEVEN as an input, and output the block selection composition signal PBLSIJ to a latch output terminal. A NOR gate 607 receives an output of the NOR gate 604 and an output of the NAND gate 605, and generates a block selection composition inversion signal PBLSIJB as a NOR response. An AND gate 608 receives the bit line equalization control signal PSEC_EQ and the PSEC block blocking signal PSEC_EVB as an output of the NAND gate 606, and generates an AND response. A NOR gate 609 receives the block selection composition inversion signal PBLSIJB and an output of the AND gate 608, and generates a NOR response. An inverter 625 inverts an output of the NOR gate 609, and outputs it as the block equalization signal PEQIJB. At this time, the output of the NOR gate 609 becomes a block equalization signal PEQIJ having a phase opposite to that of the block equalization signal PEQIJB.

The block equalization signal PEQIJB generated by the circuit block 610 of FIG. 11 is maintained as a low level for time point of from t2 to t4, such as in a waveform PEQIJB_E of FIG. 5.

In more detail, at the time t2 of FIG. 5, even block sensing decision signal PSECNTEVEN is provided as a high level and odd block sensing decision signal PSECNTODD is provided as a low level through a circuit operation of FIG. 9. Further, equalization disable signal TCKE_EQ_DISB is provided as a high level, and the block selection signals PBLSI and PBLSJ are all provided as a high level. The bit line equalization control signal PSEC_EQ is provided as a high level. Then, the block selection composition signal PBLSIJ is generated as a high level, and an output of NAND gate 601 becomes a high level. At this time, the output of the NOR gate 604 becomes a low level and the output of the NOR gate 607 also becomes a low level. Two inputs of the NOR gate 609 all become a low level, and thus a NOR response becomes a high level. Thus, the block equalization signal PEQIJB generated through the inverter 625 becomes a low level until the time point t4, such as the waveform PEQIJB_E of FIG. 5.

On the other hand, for example, when the circuit block 610 of FIG. 11 is changed into a circuit configuration related to an odd block, the even and odd block sensing decision signals PSECNTEVEN/ODD are switched and then applied to NAND gates 601 and 606. For example, the even block sensing decision signal PSECNTEVEN is applied to another input terminal of the NAND gate 601, and the odd block sensing decision signal PSECNTODD is applied to another input terminal of the NAND gate 606. In this case, the generated block equalization signal PEQIJB is maintained as a high level for the time point of from t2 to t4 like waveform PEQIJB_O of FIG. 5.

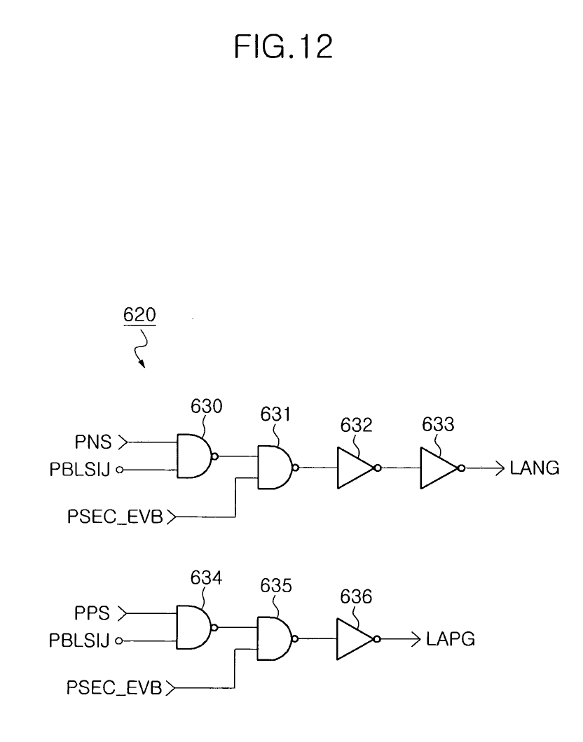

FIG. 12 illustrates an example of a circuit block 620 included in the row decoder and control block 600 shown in FIG. 7. The circuit block 620 generates an n-type/p-type sense amplifier drive signal LANG/LAPG per even block or odd block by using an n-type and p-type sense amplifier control signal PNS/PPS, a block selection composition signal PBLSIJ, and a PSEC block blocking signal PSEC_EVB. In FIG. 12, the n-type sense amplifier drive signal LANG may be generated by using NAND gates 630 and 631, and a connection configuration of inverters 632 and 633. The p-type sense amplifier drive signal LAPG may be generated by using a connection configuration of inverter 636 and NAND gates 634 and 635. To obtain a waveform as shown in the aggressor bit line BL/BLB_E of FIG. 5, the n-type sense amplifier drive signal LANG that independently has a high period at a time point between t2 to t5 of FIG. 5, such as shown by waveform LANG_E of FIG. 5, is generated through the inverter 633 of FIG. 12, and through the inverter 636, p-type sense amplifier drive signal LAPG independently having a low period at a time point between t2 to t5 of FIG. 5, such as shown by waveform LAPG_E of FIG. 5, is generated.

Meanwhile, to obtain a waveform as shown in victim bit line BL/BLB_O of FIG. 5, n-type sense amplifier drive signal LANG that independently has a low period at a time point between t2 to t5 shown in FIG. 5, such as shown by waveform LANG_O of FIG. 5, is generated through the inverter 633 of FIG. 12. Through the inverter 636, p-type sense amplifier drive signal LAPG independently having a high period at a time point between t2 to t5 of FIG. 5, such as shown by the waveform LAPG_O of FIG. 5, is generated.

For example, when the circuit block 620 of FIG. 12 is used to drive sense amplifiers coupled to an aggressor bit line, another input terminal of NAND gates 631 and 635 is each locked at a low level since the PSEC block blocking signal PSEC_EVB output from the NAND gate 606 of FIG. 11 becomes a low level after the time point t2 of FIG. 5. Accordingly, outputs of the NAND gates 631 and 635 all become a high level regardless of an output level of NAND gates 630 and 634. A high level of the NAND gate 631 is passed sequentially through inverters 632 and 633, and is output as n-type sense amplifier drive signal LANG of a high level, such as the waveform LANG_E of FIG. 5. Further, a high level of NAND gate 635 is output as p-type sense amplifier drive signal LAPG of a low level, such as the waveform LAPG_E of FIG. 5, through the inverter 636. Therefore, sense amplifiers coupled to aggressor bit line are continuously enabled, and as shown after the time point t2 of FIG. 5, the aggressor bit line BL/BLB_E is continuously maintained as a sensing state.

For example, when the circuit block 620 of FIG. 12 is used for driving sense amplifiers coupled to a victim bit line, another input terminal of NAND gates 631 and 635 is each locked at a high level since the PSEC block blocking signal PSEC_EVB output from the NAND gate 606 of FIG. 11 becomes a high level after the time point t2 of FIG. 5. Accordingly, outputs of the NAND gates 631 and 635 all become a low level since a high level is applied to one of both input terminals of each of the NAND gates 631 and 635 and high level signals caused by a block selection composition signal PBLSIJ having a low level are applied from the NAND gates 630 and 634 to the input terminals, connected thereto, of the NAND gates 631 and 635. A low level of the NAND gate 631 is output as n-type sense amplifier drive signal LANG of a low level after the time point t2, such as by waveform LANG_O of FIG. 5, sequentially through the inverters 632 and 633. Further, a low level of the NAND gate 635 is output as p-type sense amplifier drive signal LAPG of a high level, such as by the waveform LAPG_O of FIG. 5, through the inverter 636. Accordingly, sense amplifiers coupled to the victim bit line are disabled, and victim bit line BL/BLB_O at a time point between t2 to t4 shown in FIG. 5 is maintained as an equalization state of a VBL level.

It will be apparent to those skilled in the art that modifications and variations can be made to example embodiments without deviating from the spirit or scope of example embodiments. Thus, it is intended that example embodiments cover any such modifications and variations of example embodiments, provided they come within the scope of the appended claims and their equivalents.

For example, in other cases, a detailed connection configuration in functional circuits related to a bridge detection or an enable time adjustment of a word line may be changed without deviating from the spirit of example embodiments.

Furthermore, although DRAM is shown as an example in the above-description, a technical spirit of example embodiments is applicable to other volatile memories, devices internally employing a DRAM cell, etc.

In the drawings and specification, there have been disclosed example embodiments and, although specific terms are employed, they are used in a generic and descriptive sense just and not for limitation, the scope of example embodiment being set forth in the following claims.

What is claimed is:

1. A method of detecting a bit line bridge in a semiconductor memory device, comprising:
enabling a sensing state for an even bit line connected to an even sense amplifier and an odd bit line connected to an odd sense amplifier, where the odd bit line is adjacent to the even bit line;
first changing the odd bit line to a pre-charge state to pre-charge the odd bit line while maintaining the sensing state of the even bit line;
second changing the odd bit line to a floating state; and
applying a pause time period.

2. The method of claim 1, wherein the enabling includes enabling a first word line, where the first word line intersects the odd and even bit lines, and activating the even and odd sense amplifiers.

3. The method of claim 2, further comprising:
sustaining the pre-charge state of the odd bit line when the first word line is enabled after the first changing.

4. The method of claim 3, further comprising:
enabling a second word line adjacent to the first word line after the applying.

5. The method of claim 4, further comprising:
sensing the odd bit line for a read fail to determine whether there is the bit line bridge between the even and odd bit lines.

6. The method of claim 5, wherein the sensing further includes reading a memory cell coupled to the odd bit line and the first word line for the read fail.

7. The method of claim 6, wherein the sensing further includes determining a potential difference between the odd and even bit lines.

8. The method of claim 7, wherein the sensing further includes activating the odd sense amplifier.

9. The method of claim 1, wherein the first changing includes deactivating the odd sense amplifier.

10. The method of claim 1, wherein the second changing includes disabling a pre-charge signal coupled to the odd sense amplifier.

11. The method of claim 10, wherein the second changing further includes disabling the first word line.

12. The method of claim 10, wherein the second changing further includes maintaining the first word line as enabled.

13. The method of claim 1, wherein the applying maintains the pause time such that a leakage path of the odd sense amplifier is cut off.

14. A method of detecting a bit line bridge in a semiconductor memory device, the method comprising:
maintaining a potential difference of an aggressor bit line pair in a sensing state by activating a first bit line sense amplifier coupled to the aggressor bit line pair;
pre-charging a victim bit line pair coupled to a second bit line sense amplifier;
maintaining a pause time in a state such that a leakage path of the second bit line sense amplifier is cut off; and
reading a memory cell connected to the victim bit line after the pause time.

15. The method of claim 14, wherein the reading includes checking the memory cell for a read fail caused by the bit line bridge between a first bit line of the victim bit line pair and a second bit line of the aggressor bit line pair by activating the second bit line sense amplifier.

16. The method of claim 15, wherein the reading further includes determining a potential difference between the aggressor bit line and the victim bit line by deducting a pre-charge voltage from an array internal power voltage or by deducting an array ground power voltage from a pre-charge voltage.

17. The method of claim 14, wherein the pre-charging includes deactivating the second bit line sense amplifier.

18. The method of claim 14, further comprising:
changing the victim bit line to a floating state, where the changing includes disabling a first word line coupled to the memory cell and intersecting the victim and aggressor bit lines.

19. The method of claim 18, wherein the changing further includes disabling the first word line.

20. The method of claim 18, wherein the changing further includes maintaining the first word line as enabled.
